(19) United States
(12) Patent Application Publication
(10) Pub. No.: US 2009/0286405 A1
(43) Pub. Date: Nov. 19, 2009

(54) SHOWER PLATE, AND PLASMA PROCESSING APPARATUS, PLASMA PROCESSING METHOD AND ELECTRONIC DEVICE MANUFACTURING METHOD USING THE SHOWER PLATE

(75) Inventors: Masahiro Okesaku, Ishikawa (JP); Tetsuya Goto, Miyagi (JP); Tadahiro Ohmi, Miyagi (JP); Kiyotaka Ishibashi, Tokyo (JP)

Correspondence Address: PEARNE & GORDON LLP, 1801 EAST 9TH STREET, SUITE 1200, CLEVELAND, OH, 44114-3108, US

(73) Assignees: TOKYO ELECTRON LIMITED, Tokyo (JP); NATIONAL UNIVERSITY CORPORATION TOHOKU UNIVERSITY, Miyagi (JP)

(21) Appl. No.: 12/304,289

(22) PCT Filed: Jun. 13, 2007
(86) PCT No.: PCT/JP2007/061858

§ 371 Date: Jul. 29, 2009

(30) Foreign Application Priority Data
Jun. 13, 2006 (JP) 2006-163526

(51) Int. Cl. H01L 21/3065; C23C 16/00; H01L 21/30; B01J 19/08

(52) U.S. Cl. 438/710; 156/345.34; 118/723 R; 438/758; 422/186.05; 257/E21.218; 257/E21.211

(57) ABSTRACT

Provided is a shower plate in which there's no need for a cover plate. The shower plate 105 is disposed in a processing chamber 102 of a plasma processing apparatus, for discharging a plasma excitation gas to generate plasma in the processing chamber 102, and the shower plate 105 includes a horizontal hole 111 for introducing the plasma excitation gas into the shower plate 105 from a gas inlet port 110 of the plasma processing apparatus; and a vertical hole 112 communicating with the horizontal hole 111, wherein the shower plate 105 is formed as a single body.

### TECHNICAL FIELD

The present invention relates to a shower plate used in a plasma processing apparatus, more particularly, a microwave plasma processing apparatus, and a plasma processing apparatus, a plasma processing method and an electronic device manufacturing method using the shower plate.

### BACKGROUND ART

A plasma process and a plasma processing apparatus are essential for the manufacture of a recent ultrafine semiconductor device called a deep sub-micron device or deep sub-quarter micron device having a gate length of about 0.1 μm or less, or the manufacture of a flat panel display of a high-resolution including a liquid crystal display.

Various plasma excitation methods are conventionally adopted for the plasma processing apparatus for use in the manufacture of the semiconductor device or the liquid crystal display. Especially, a high-frequency excitation plasma processing apparatus of a parallel plate type or an inductively coupled plasma processing apparatus is generally utilized.

It is desirable that the plasma processing apparatus generates plasma having high electron density and uniformity. In the conventional plasma processing apparatus, however, since the plasma generation has been non-uniform and the electron density has been found to be high only in a limited region, it has been difficult to perform a uniform process over the entire surface of a target substrate with a high processing rate, i.e., with a high throughput.

Especially, such problem becomes a serious drawback when processing a substrate having a large diameter. Besides, the conventional plasma processing apparatus also has other crucial problems such as the high electron temperature, the occurrence of damage on a semiconductor device formed on the target substrate, the occurrence of a high level metal contamination due to sputtering a processing chamber wall, and so forth. Furthermore, as for the conventional plasma processing apparatus, it is getting more and more difficult to meet recent demands for further miniaturization of semiconductor devices or liquid crystal displays and enhancement of productivity.

Meanwhile, there has been proposed a microwave plasma processing apparatus which employs high-density plasma excited by a microwave electric field without using a DC magnetic field. As disclosed in Patent Document 1, such plasma processing apparatus has a configuration in which microwave is emitted into a processing chamber from a planar antenna (radial line slot antenna) having a number of slots arranged to generate the microwave in a uniform manner, and plasma is excited by ionizing a gas in the processing chamber by an electric field of the microwave.

Since the microwave plasma excited by the plasma processing apparatus can achieve high plasma density over a wide area directly under the antenna, it is possible to perform a uniform plasma process in a short period of time. Further, the electron temperature is low because the plasma is generated by the microwave, and the damage or the metal contamination of the target substrate can be prevented. Moreover, since it is possible to excite the plasma uniformly even on a large-area substrate, the plasma processing apparatus can be effectively applied to a large-size liquid crystal display manufacturing process or a semiconductor device manufacturing process using a semiconductor substrate having a large diameter.

In such plasma processing apparatus, a shower plate is typically used to uniformly supply a plasma excitation gas into the processing chamber.

As described in Patent Document 2, a conventional shower plate includes a shower plate main body and a cover plate firmly attached to each other by a sealing O-ring. A gas charging space is formed by providing a groove in the cover plate or in the shower plate main body, and the gas is discharged from gas discharge holes communicating with the gas charging space.

However, the shower plate having the above-described configuration has problems as follows.

First, there arises a maintenance issue of the shower plate and a stability problem of the plasma. That is, to detach the shower plate for maintenance such as cleaning, the shower plate main body and the cover plate need to be suspended and lifted up separately or need to be integrated as one body with a special jig to be suspended and lifted up at the same time. However, the suspension and lift up process thereof or the installation of the jig has been troublesome. Further, if the jig is previously installed in the processing chamber for the integration of the shower plate main body and the cover plate, the stability of the plasma is deteriorated due to the presence of the jig.

Moreover, even in case that it is attempted to suspend and lift up the shower plate main body and the cover plate together by using a special suspension jig without their integration beforehand, a cutoff formation process or the like needs to be performed on the shower plate main body and the cover plate to hold the suspension jig, which is troublesome. Furthermore, the formation of the cutoff or the like may incur damage or deterioration of the plasma stability. Besides, the suspension and lift up process is also difficult, and deformation of the shower plate is highly likely to occur during the suspension and lift up process. The deformation of the shower plate would result in deterioration of the plasma stability.

Furthermore, as for the conventional shower plate, since it is necessary to perform position alignment on the shower plate main body and the cover plate, the maintenance work needs to include the position alignment, which is troublesome, too. If the position alignment is not sufficient, the stability of the generated plasma would be deteriorated.

Further, in the conventional shower plate, the above-mentioned sealing O-ring is used to firmly attach the shower plate main body to the cover plate. As a sealing O-ring, one having a low loss against microwave is used. However, since the microwave electric field is strong inside the shower plate, the O-ring itself is likely to burn when abnormal discharge occurs at a portion of the sealing O-ring or when the shower head is overheated. In case that the O-ring is burnt, its sealing effect is deteriorated, of course. Thus, the maintenance work is required whenever such occasion arises. Further, the abnormal discharge inside the shower plate may result in damage of the shower plate.
Patent Document 1: Japanese Patent Laid-open Publication No. H9-63793
Patent Document 2: Japanese Patent Laid-open Publication No.

### DISCLOSURE OF THE INVENTION

### Problems to Be Solved by the Invention

In view of the foregoing, the present invention provides a shower head capable of solving the above-stated problems. Specifically, the present invention provides a shower plate, in which there's no need for a cover plate.

Further, the present invention provides a shower plate featuring high plasma stability and facilitating maintenance work.

Furthermore, the present invention prevents the occurrence of abnormal discharge inside a shower plate.

Furthermore, the present invention eliminates the necessity of maintenance work due to the soot on a sealing O-ring.

### Means for Solving the Problems

The present invention is related to a shower plate disposed in a processing chamber of a plasma processing apparatus, for discharging a plasma excitation gas to generate plasma in the processing chamber, wherein a shower plate main body and a cover plate is integrally formed. That is, by forming the shower plate as a single body, the shower plate is provided with a horizontal hole for introducing the plasma excitation gas into the shower plate from a gas inlet port of the plasma processing apparatus; and a vertical hole communicating with the horizontal hole, for discharging the plasma excitation gas.

In this manner, by installing, in the single body shower plate, the horizontal holes for introducing the plasma excitation gas into the shower plate from the gas inlet port of the plasma processing apparatus, there is no need for installing a cover plate separately as in the conventional shower plate. Accordingly, it is unnecessary to perform position alignment on the cover plate and the shower plate main body, and the detachment process or the suspension and lift up process during a cleaning work becomes easy, thereby facilitating the maintenance work. Further, since a special jig for the detachment process or the suspension and lift up process is not necessary, the impairment of the plasma stability due to the presence of the jig can be avoided.

Moreover, since the detachment process or the suspension and lift up process becomes easy, the deformation of the shower plate can be prevented during this process, so that the deterioration of the plasma stability can be further suppressed. Furthermore, since a sealing O-ring for firmly attaching the shower plate main body to the cover plate is unnecessary, the generation of abnormal discharge due to the sealing O-ring can also be avoided. Therefore, the soot on the sealing O-ring is also prevented.

In the shower plate of the present invention, it is desirable that the horizontal hole is formed toward a central portion of the shower plate from a side surface thereof, and the horizontal hole is provided at plural locations along a circumferential direction of the shower plate in approximately same intervals.

### Effect of the Invention

In accordance with the present invention, there is no need for installing a cover plate separately as in the conventional shower plate, so that the detachment process or the suspension and lift up process during a cleaning work becomes easy, thereby facilitating the maintenance work and improving the stability of the plasma.

Further, the generation of abnormal discharge inside the shower plate can be suppressed, so that damage on the shower plate is prevented, thereby enhancing plasma processing quality and yield.

### BEST MODE FOR CARRYING OUT THE INVENTION

Hereinafter, examples of the present invention will be described based on embodiments.

### Embodiments

FIG. 1 illustrates a microwave plasma processing apparatus to which the present invention is applied. The illustrated microwave plasma processing apparatus includes a processing chamber 102 evacuated through a plurality of gas exhaust ports 101, and a supporting table 104 for supporting a target substrate 103 is disposed in the processing chamber 102. The processing chamber 102 defines a ring-shaped space around the supporting table 104 in order to evacuate the processing chamber 102 uniformly, and the plurality of gas exhaust ports 101 is arranged at a same interval, i.e., in axial symmetry with respect to the target substrate 103, while communicating with the space. With such arrangement of the gas exhaust ports 101, the processing chamber 102 can be evacuated through the gas exhaust ports 101 uniformly.

Disposed at an upper portion of the processing chamber 102 via a sealing O-ring 106 is a shower plate 105 which has a diameter of about 408 mm and a dielectric constant of about 9.8, and is made of dielectric alumina having a low microwave dielectric loss (equal to or less than about 1×10⁻³, desirably equal to or less than about 5×10⁻⁴) The shower plate 105 is installed at a position corresponding to the target substrate 103 on the supporting table 104, and constitutes a part of an exterior wall of the processing chamber 102. Further, at a wall surface 107 constituting the processing chamber 102, a ring-shaped space 109 surrounded by two sealing O-rings 108 and the lateral surface of the shower plate 105 is provided at a position corresponding to the lateral side of the shower plate 105. The ring-shaped space 109 communicates with a gas inlet port 110 for introducing a plasma excitation gas.

Meanwhile, a multiplicity of horizontal holes 111 each having a diameter of about 1 mm is provided in the lateral side of the shower plate 105, i.e., in a shower plate main body, which is a single body, so as to be opened toward the center of the shower plate 105 in horizontal direction. At the same time, a number (e.g., about 230) of vertical holes 112 is opened to communicate with the processing chamber 102 as well as with the horizontal holes 111.

FIG. 2 illustrates the arrangement of the horizontal holes 111 and the vertical holes 112 of the shower plate 105, when viewed from the top. FIG. 3 is a schematic perspective view showing the arrangement of the horizontal holes 111 and the vertical holes 112. The horizontal holes 111 are elongated toward a central portion of the shower plate 105 from its lateral side, and are arranged at an approximately same interval along the circumference of the shower plate 105, thus forming a radial shape as a whole.

Further, FIG. 4 illustrates a detail of the vertical hole 112. The vertical hole 112 includes a first vertical hole 112a having a diameter of about 10 mm and a depth of about 10 mm provided on the side of the processing chamber 102; and a second vertical hole 112b having a diameter of about 1 mm provided on the front part thereof (i.e., on the gas introducing side), and communicates with the horizontal hole 111. Further, installed in the first vertical hole 112a in sequence, when viewed from the side of the processing chamber 102, are a ceramics member 113, which has a height of about 5 mm and made of alumina extrusion molding product and opened through a plurality of gas discharge holes 113a each having a diameter of about 50 μm; and a porous ceramics gas flowing body 114 of a columnar shape, which has a diameter of about 10 mm and a height of about 5 mm and provided with pores communicating in a gas flow direction.

The formations of the horizontal holes 111 and the vertical holes 112 are performed as follows, for example.

First, when forming the horizontal holes 111, there is prepared a long drill having a dimension capable of acquiring a hole diameter of about Ø1 mm after sintering and shrinking in the stage of a green molded body obtained by compressing and molding a sintering source powder. The horizontal holes 111 have various different lengths, as shown in FIG. 2, and since the longest hole is about 250 mm, the long drill needs to have a length equivalent thereto or greater. Thus, it is desirable to use the long drill made of a super hard metal having a Young's modulus equal to or greater than about 500 GPa. In case that the length of the horizontal hole is short, the hole is formed by using a short drill made of the above-stated material, and in case that the length of the hole is long, a base hole is first processed with the short drill and then the long hole is processed by drilling along the base hole with the long drill, whereby it becomes possible to form the horizontal hole having the concentricity and the straightness within the range of about 2 μm.

As for the vertical hole 112, after processing the second vertical hole 112b with a short drill made of a super hard metal having a dimension capable of acquiring a hole diameter of about Ø1 mm after sintering and shrinking, the first vertical hole 112a is processed with a super hard tool capable of acquiring a hole diameter of about Ø10 mm after sintering and shrinking.

Now, a method for introducing a plasma excitation gas into the processing chamber will be explained with reference to FIG. 1. The plasma excitation gas from the gas inlet port 110 is introduced into the ring-shaped space 109 and finally introduced into the processing chamber 102 through the gas discharge holes 113a, which are provided at leading end portions of the vertical holes 112, via the horizontal holes 111 and the vertical holes 112.

Provided on the top surface of the shower plate 105 are a slot plate 115 of a radial line slot antenna opened by a number of slits for radiating microwave; a wavelength shortening plate 116 for propagating the microwave in a diametric direction, and a coaxial waveguide 117 for introducing the microwave into the antenna. Further, the wavelength shortening plate 116 is interposed between the slot plate 115 and a metal plate 118. The metal plate 118 is provided with a cooling flow path 119.

With this configuration, the plasma excitation gas supplied from the shower plate 105 is ionized by the microwave radiated from the slot plate 115, so that high-density plasma is generated in an area within several millimeters directly under the shower plate 105. The generated plasma reaches the target substrate 103 by the diffusion. Besides the plasma excitation gas, a gas for actively generating radicals, e.g., an oxygen gas or an ammonia gas may also be introduced from the shower plate 105.

In the illustrated plasma processing apparatus, a lower shower plate 120 made of a conductor such as aluminum, stainless steel or the like is disposed between the shower plate 105 and the target substrate 103 in the processing chamber 102. The lower shower plate 120 includes a plurality of gas flow paths 120a through which a processing gas supplied from a processing gas supply port 121 is provided to the target substrate 103 in the processing chamber 102, and the processing gas is discharged into a space between the lower shower plate 120 and the target substrate 103 through a multiplicity of nozzles 120b formed in gas flow paths 120a's surfaces facing the target substrate 103. Here, in case of a plasma-enhanced chemical vapor deposition (PECVD) process, a silane gas or a disilane gas is introduced as the processing gas when forming a silicon-based thin film, whereas a C₅F₈ gas is introduced when forming a low dielectric film. Furthermore, a CVD process using an organic metal film as the processing gas is also possible. Further, in case of a reactive ion etching (RIE) process, a C₅F₈ gas and an oxygen gas are introduced when etching a silicon oxide film, whereas a chlorine gas or a HBr gas is introduced when etching a metal film or silicon. When ion energy is needed for the etching, an RF power supply 122 is connected to an electrode inside the supporting table 104 via a capacitor, and a self-bias voltage is generated on the target substrate 103 by applying an RF power thereto. The kind of the flowing processing gas is not limited to the above-mentioned examples, but the kind of the flowing gas and the pressure can be determined depending on the process.

The lower shower plate 120 is provided with an opening 120c between the neighboring gas flow paths 120a. The opening 120c has a size capable of allowing the plasma, which is excited by the microwave in the region above the lower shower plate 120, to pass therethrough effectively so as to be diffused into the space between the target substrate 103 and the lower shower plate 120.

Further, a heat flow introduced into the shower plate 105 as a result of the exposure to the high-density plasma is cooled by a coolant such as water flowing through the cooling flow path 119 via the slot plate 115, the wavelength shortening plate 116 and the metal plate 118.

Referring to FIG. 4, in the present embodiment, the plurality of gas discharge holes 113a, which is opened in the columnar ceramics member 113 made of alumina material, each has a diameter of about 50 μm, which value is smaller than twice the sheath thickness 40 μm of the high-density plasma of about 10¹² cm³, but larger than twice the sheath thickness 10 μm of the high-density plasma of about 10¹³ cm⁻³.

Further, the thickness d of the sheath formed on the surface of an object in contact with the plasma is obtained from the following equation.

$$d = 0.606 {{λ}_{D} ( \frac{2 {V}_{0}}{{T}_{e}} )}^{3 / 4} \qquad [ Eq . 1 ]$$

Here, V₀ represents a potential difference (V) between the plasma and the object; Tₑ indicates an electron temperature (eV); and λ_{D} is the Debye length calculated by the following equation.

$${λ}_{D} = \sqrt{\frac{{ɛ}_{0} k {T}_{e}}{{n}_{e} {e}^{2}}} = 7.43 \times {10}^{3} \sqrt{\frac{{T}_{e} [ eV ]}{{n}_{e} [ {m}^{- 3} ]}} [ m ] \qquad [ Eq . 2 ]$$

Here, E₀ indicates a vacuum permeability; k represents a Boltzmann constant; and nₑ stands for an electron density of the plasma.

As shown in Table 1, if the electron density of the plasma increases, the Debye length decreases. Thus, it can be said that the smaller the hole diameter of the gas discharge hole 113a is, the more desirable it is in the aspect of preventing the backflow of the plasma.

TABLE 1
Tₑ = 2 eV, V₀ = 12 V

| Plasma | Debye | Sheath |
|---|---|---|
| Density(cm⁻³) | Length(mm) | Thickness(mm) |
| 10¹³ | 0.003 | 0.01 |
| 10¹² | 0.011 | 0.04 |
| 10¹¹ | 0.033 | 0.13 |
| 10¹⁰ | 0.105 | 0.41 |

Further, by setting the length of the gas discharge hole 113a to be longer than a mean free path, which is a mean distance for electrons to travel before electrons are dispersed, the backflow of the plasma can be greatly reduced. In Table 2, mean free paths of electrons are provided. The mean free path is in inverse proportion to the pressure, and it becomes 4 mm at 0.1 Torr. Though the mean free path actually becomes shorter than 4 mm because the pressure at the gas inlet side of the gas discharge hole 113a is high, in the present embodiment, the length of the gas discharge hole 113a having the diameter of about 50 μm is set to be 5 mm, which is longer than the mean free path.

TABLE 2
Mean free path of electrons under Ar gas atmosphere

| Pressure (P) | Mean free path (λen) |
|---|---|
| (Torr) | (mm) |
| 10 | 0.04 |
| 1 | 0.4 |
| 0.1 | 4 |

λen(mm) = 0.4/P(Torr)

Here, since the mean free path is literally a mean distance, it should be noted that there statistically exist electrons which proceed a longer distance without being dispersed. Accordingly, in the present embodiment, the porous ceramics gas flowing body 114 having pores communicating in the gas flowing direction is installed on the gas inlet side of the gas discharge hole 113a.

The porous ceramics gas flowing body 114 is made of a material having an average crystal diameter equal to or less than about 10 μm, desirably equal to or less than about 5 μm; a porosity ranging from about 20 to 75%; a maximum pore diameter equal to or less than about 75 μm; and a flexural strength equal to or greater than about 30 MPa.

To prevent abnormal discharge in the second vertical hole 112b due to the backflow of the plasma through the pores, the pore diameter is set to be equal to or less than twice the sheath thickness of the high-density plasma formed directly under the shower plate 105, desirably, equal to or less than the sheath thickness. The porous ceramics gas flowing body 114 of the present embodiment ensures the gas flowability by the communicating pores and has a gas flow path bent in a zigzag shape, and provided therein is a multiplicity of narrow passages equal to or less than about 5 μm, not greater than about 10 μM at maximum. Further, the size of the narrow passage is equal to or less than about 10 μM, which is equivalent to the sheath thickness of the high-density plasma of 10¹³ cm⁻³. With this configuration, the present shower plate can also be used for the high-density plasma of 10¹³ cm⁻³.

With the shower plate 105 having the above-described configuration, since the horizontal holes 111 for introducing the gas from the gas inlet port 111 are installed in the shower plate main body, there is no need for installing a cover plate separately as in the conventional shower plate. Accordingly, the detachment process or the suspension and lift up process during a cleaning work becomes easy, thereby facilitating the maintenance work. Further, since a special jig for the detachment process or the suspension and lift up process is not necessary, the impairment of the plasma stability due to the presence of the jig can be avoided. Moreover, since the detachment process or the suspension and lift up process becomes easy, the deformation of the shower plate can be prevented during this process, so that the deterioration of the plasma stability can be further suppressed. Moreover, since a sealing O-ring for firmly attaching the shower plate main body to the cover plate is unnecessary, the generation of abnormal discharge due to the sealing O-ring can also be avoided.

Moreover, in the present embodiment, the backflow of the plasma toward the gas inlet side of the vertical hole 112 can be prevented by installing the porous ceramics gas flowing body 114 on the upstream side of the gas discharge hole 113a. Therefore, the generation of abnormal discharge or gas deposition inside the shower plate 105 can be suppressed, so that the deterioration of yield or transmission efficiency of the microwave for exciting the plasma can be prevented. Furthermore, an efficient plasma excitation is enabled without reducing the flatness of the surface in contact with the plasma. Besides, since the gas discharge holes 113a are formed in the ceramics member 113 separate from the shower plate 105 by the extrusion molding method or the like, long and minute gas discharge holes each having a diameter equal to or less than about 0.1 mm can be more easily formed in comparison with a case of forming the gas discharge holes in the shower plate by a hole processing.

In addition, the porous ceramics gas flowing body 114 and the ceramics member 113 are formed of a ceramics material having a high purity and a dielectric loss equal to or less than about 1×10⁻³ desirably equal to or less than about 5×10⁻⁴.

Further, as a result of supplying the plasma excitation gas to the target substrate 103 uniformly and discharging the processing gas to the target substrate 103 from the lower shower plate 120 via the nozzles 120b, there is generated a uniform flow of the processing gas from the nozzles 120b of the lower shower plate 120 toward the target substrate 103, resulting in a reduction of processing gas components returning to the upper portion of the shower plate 105. As a consequence, decomposition of processing gas molecules as a result of excessive dissociation due to exposure to the high-density plasma can be suppressed, and deterioration of the microwave introducing efficiency due to deposition of the processing gas onto the shower plate 105 is unlikely to occur, though the processing gas is a deposition gas. Therefore, the time of the cleaning process can be shortened, while the process stability and reproducibility can be improved, resulting in enhancement of productivity and realization of high-quality substrate processing.

Besides, the numbers, the diameters and the lengths of the first vertical holes 112a and the second vertical holes 112b, and the number, the diameter and the length of the gas discharge holes 113a opened in the ceramics member 113 are not limited to the present embodiments.

### INDUSTRIAL APPLICABILITY

The shower plate of the present invention is applicable to various plasma processing apparatuses such as a high frequency excitation plasma processing apparatus of a parallel plate type, an inductively coupled plasma processing apparatus, and so forth, in addition to the microwave plasma processing apparatus.

### BRIEF DESCRIPTION OF THE DRAWINGS

FIG. 1 is a microwave plasma processing apparatus to which the present invention is applied;

FIG. 2 is arrangement of horizontal holes and vertical holes of a shower plate illustrated in FIG. 1 when viewed from the top;

FIG. 3 is a schematic perspective view showing the arrangement of the horizontal holes and the vertical holes of the shower plate illustrated in FIG. 1; and

FIG. 4 is a detail of a vertical hole of the shower plate illustrated in FIG. 1.

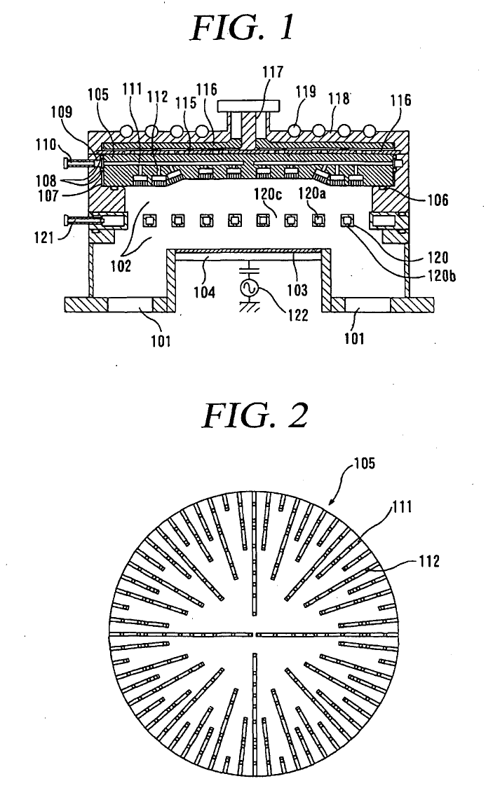

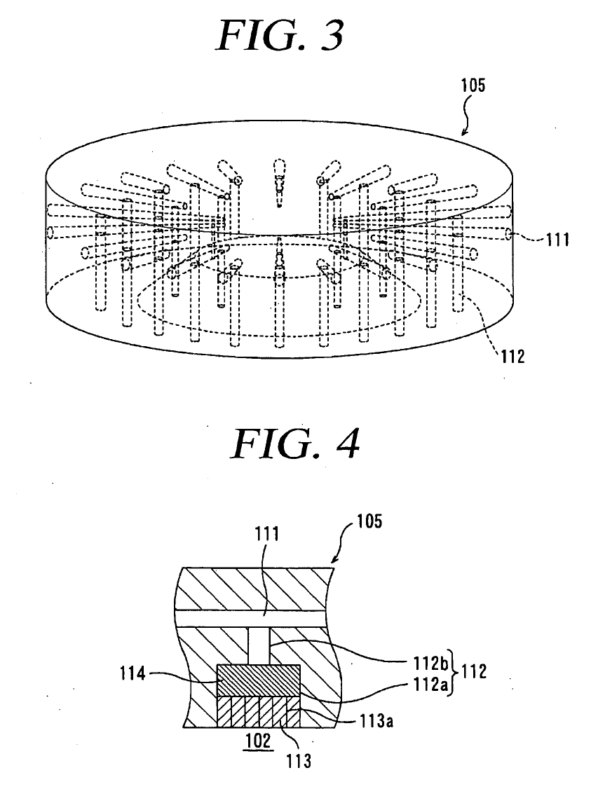

### EXPLANATION OF CODES

101: Gas exhaust ports
102: Processing chamber
103: Target substrate
104: Supporting table
105: Shower plate
106: Sealing O-ring
107: Wall surface
108: Sealing O-ring
109: Ring-shaped space
110: Gas inlet port
111: Horizontal hole
112: Vertical hole
112a: First vertical hole
112b: Second vertical hole
113: Ceramics member
113a: Gas discharge hole
114: Porous ceramics gas flowing body
115: Slot plate
116: Wavelength shortening plate
117: Coaxial waveguide
118: Metal plate
119: Cooling flow path
120: Lower shower plate
120a: Gas flow path
120b: Nozzle
120c: Opening
121: Processing gas supply port
122: RF power supply

What is claimed is:

1. A shower plate disposed in a processing chamber of a plasma processing apparatus, for discharging a plasma excitation gas to generate plasma in the processing chamber, the shower plate comprising:
a horizontal hole for introducing the plasma excitation gas into the shower plate from a gas inlet port of the plasma processing apparatus; and
a vertical hole communicating with the horizontal hole, for discharging the plasma excitation gas,
wherein the shower plate is formed as a single body.

2. The shower plate of claim 1, wherein the horizontal hole is formed toward a central portion of the shower plate from a side surface thereof.

3. The shower plate of claim 2, wherein the horizontal hole is provided at plural locations along a circumferential direction of the shower plate.

4. A plasma processing apparatus provided in a processing chamber with a shower plate as claimed in any one of claims 1 to 3.

5. A plasma processing method comprising:
supplying a plasma excitation gas into a plasma processing apparatus by using a shower plate as claimed in any one of claims 1 to 3;
generating plasma by exciting the supplied plasma excitation gas by microwave; and
performing oxidation, nitridation, oxynitridation, CVD, etching or plasma irradiation on a substrate by using the plasma.

6. An electronic device manufacturing method comprising a process for processing a substrate by a plasma processing method as claimed in claim 5.
